(19) United States
(12) Patent Application Publication
(10) Pub. No.: US 2006/0163671 A1
(43) Pub. Date: Jul. 27, 2006

(54) SILICIDE CAP STRUCTURE AND PROCESS FOR REDUCED STRESS AND IMPROVED GATE SHEET RESISTANCE

(75) Inventors: Levent Gulari, Marlboro, NY (US); Kevin E. Mello, Fishkill, NY (US); Robert J. Purtell, Mohegan Lake, NY (US); Yun-Yu Wang, Poughquag, NY (US); Keith K. Wong, Wappingers Falls, NY (US)

Correspondence Address: SCULLY SCOTT MURPHY & PRESSER, PC, 400 GARDEN CITY PLAZA, SUITE 300, GARDEN CITY, NY, 11530, US

(73) Assignee: INTERNATIONAL BUSINESS MACHINES CORPORATION, Armonk, NY (US)

(21) Appl. No.: 10/905,949

(22) Filed: Jan. 27, 2005

(51) Int. Cl. H01L 29/76; H01L 29/94; H01L 31/062; H01L 31/113; H01L 31/119

(52) U.S. Cl. 257/388

(57) ABSTRACT

A suicide cap structure and method of fabricating a suicide cap having a low sheet resistance. The method provides a semiconductor substrate and a MOSFET structure comprising a gate insulator on the substrate, an Si-containing gate electrode on the gate insulator layer, and source/drain diffusions. Atop the gate electrode and source/drain diffusions is formed a layer of metal used in forming a silicide region atop the transistor gate electrode and diffusions; an intermediate metal barrier layer formed atop the silicide forming metal layer; and, an oxygen barrier layer formed atop the intermediate metal barrier layer. As a result of annealing the MOSFET structure, resulting formed silicide regions exhibit a lower sheet resistance. As the intermediate metal barrier layer comprises a material exhibiting tensile stress, the oxygen barrier layer may comprise a compressive material for minimizing a total mechanical stress of the cap structure and underlying layers during the applied anneal.

### CROSS-REFERENCE TO RELATED APPLICATIONS

The present invention relates to commonly-owned, co-pending U.S. patent application Ser. No. 10/709,534 filed on May 12, 2004 entitled “Method For Controlling Voiding and Bridging In Silicide Formation” the whole contents and disclosure of which are incorporated by reference as if fully set forth herein.

### FIELD OF THE INVENTION

The present invention relates to semiconductor device manufacturing, and more particularly to a self-aligned metal silicide contact structure that exhibits lower sheet resistance and, a method of manufacture. The present invention is also related to complementary metal oxide semiconductor (CMOS) structures which include the self-aligned silicide contacts.

### BACKGROUND OF THE INVENTION

A key to continued CMOS miniaturization is the ability to scale down the horizontal and vertical dimensions of the semiconductor device while increasing speed, decreasing power, and operating at lower voltages. As devices are scaled below 0.25 micron, the sheet resistance and contact resistance of the transistor contacts must be maintained at low values. A further requirement is that the source-to-substrate leakage be maintained low in order to ensure device and circuit performance without error. These requirements put stringent boundary conditions on the nature and dimension of the gate and source/drain contacts, which are typically composed of metal suicides in microprocessors, ASICS and DRAM devices. In order to obtain low sheet resistance, the suicides must have ohmic resistivity below 15 uΩ-cm and a thickness of at least 200 Å.

The self aligned silicide process, as practiced in the manufacture of semiconductor devices, involves deposition of a metal and protective cap on a Semiconductor wafer which is then heated to react the metal with the silicon in the active areas of the device, forming a conductive silicide layer. Metal deposited on insulators such as oxides and nitrides does not react and is subsequently etched off along with the cap in a subsequent stripping operation. Electrical connections can then be made to the silicided surfaces in subsequent processing steps.

Typical metals that are used to make silicided contacts are Co, Ti, and Ni. When Co reacts with silicon on the active areas of a device, there is a dimensional reduction of the material from that of the original Co metal free surface due to material densification during silicide formation. This means if one unit of metal is deposited on the top and sides of a gate structure, for example, after the silicidization process, the overall height and width of the structure will shrink to a value less than this depending on the extent of reaction on specific planes of the structure.

These dimensional changes for different parts of the device structure require that the protective cap deposited over the metal either flex due to height changes in different areas of the device below it or allow voids to open up in some places beneath it to compensate for volumetric changes occurring at various points below the cap. The subsequent differential stresses and voiding or delamination that can occur can allow Si to move into areas where it is not desired with subsequent voiding and electrical bridging. This phenomenon occurs for example in the Co/TiN system after annealing.

Currently, for self-aligned silicide processes, used ubiquitously for microprocessors and widely in DRAM technology, source/drain silicide materials having a balance of low resistivity and moderate silicon consumption are being used. Such material include Ti silicides, W silicides, Co suicides and Ni silicides.

FIGS. 1(a)-1(d) illustrate a typical self-aligned silicide (salicide) process, where ohmic contacts and the silicide atop the gate electrode are formed by deposition of a metal layer over the Si-containing surfaces (i.e., atop exposed source/drain regions and the uppermost surface of a Si-containing gate conductor) and annealing which converts the metal layer and nearby Si-containing surfaces into a silicide layer. In a typical process described with respect to FIG. 1(b), a metal film, such as cobalt, Co film 20a, or nickel, Ni film 20b, is formed over the surface of a formed transistor 15 that has been fabricated on a substrate 10 as shown in FIG. 1(a). The transistor 15 comprises a formed gate dielectric 12 and polysilicon gate electrode 14 including abutting sidewall spacers 16 and source and drain diffusion regions 18, 19 formed adjacent each side of the gate and between trench isolation regions 22. The cobalt Co or nickel Ni film 20a,b may be deposited according to conventional techniques and annealed at a pre-defined temperature range (e.g., 200° C. to 600° C.), using a magnetron sputtering method, to form an initial silicide film with a thickness ranging anywhere between 6 nm-10 nm. Then, a metal cap layer 25 of TiN is sputter deposited to a thickness of approximately 20 nm over the metal film, e.g., cobalt and nickel layers 20a,b, as shown in FIG. 1(b). Next, this is heat treated (annealed) for an amount of time in an inert gas atmosphere, such as oxygen or nitrogen, at a temperature of 500 degrees C. or higher, so as to form a cobalt monosilicide film (e.g., CoSi) 30 above the gate region and a NiSi or NiₓSi_{y} 40 above the source and drain regions. When this is done, the cobalt silicide film 30, as shown in FIG. 1(c), is formed in self-aligned manner over only the gate electrode 14 and the diffusion layers 18, 19. Then, a selective etch process is performed using a wet etchant, e.g., peroxide sulfuric solutions, to remove the unreacted metal, e.g., the top TiN and Co layers, but does not remove the formed metal silicide 30, 40, to result in the structure shown in FIG. 1(d). An optional second anneal step may be further performed at this time to form a uniform, low-resistivity cobalt disilicide (CoSi₂) or NiSi as shown in FIG. 1(d).

Additionally, the trend in silicide formation, as with junction formation, is toward utilizing annealing processes which have shorter times and high temperatures and that use lamp-based thermal annealing wherein the silicide formation is accomplished in 10-60 seconds. This minimizes side reactions, such as oxidation, inversion of suicide where polysilicon may move to the top surface of the silicide, and breaking up suicide film into islands or agglomerates, that are generally associated with increased sheet resistance (“rho”) and junction leakage. However, even rapid thermal annealing (RTA) can lead to agglomeration and increased resistance. This restricts the thermal process window for the reaction of the metal films to form low resistance contacts before the films become unstable. The tendency to agglomerate also increases as the transistor line width shrinks, further narrowing the process window for low resistance and low leakage contacts. FIG. 2 depicts potentially deleterious movement of materials during the silicide formation depicted in the process according to FIGS. 1 (a)-1 (e). For example, during RTA anneal, the TiN cap must deflect over active areas during silicide formation (No deflection over insulators). The distance it has to travel, e, is a function of metal thickness and phase formed in RTA. Mechanical energy (E) built up during deflection, e, causes voids 98 and/or bridging 99, i.e. sheet rho fliers.

Furthermore, current Silicide cap technology using TiN sputter deposition results in increased sheet rho due to nitrogen penetration into the silicide film from the TiN film deposition process. FIG. 3 depicts a plot 50 illustrating the increased resistance exhibited by a silicide cap of a low, medium and high medium nitrogen contents. Thus, as shown in FIG. 3, for example, a first plot 52 comprising wafers having circuit devices formed with a (two layer) Co/TiN cap (of medium nitrogen content) is depicted; a second plot 55 comprising wafers having circuit devices formed with a (two layer) Co/TiN cap (of high nitrogen content) is depicted; and, a third plot 58 comprising wafers having circuit devices formed with a (two layer) Co/TiN cap (of low nitrogen content) is depicted. However, these effects are reduced by the use of a Tungsten (W) cap as shown in the plot 60 depicted in FIG. 4 which shows two plots of wafers with a first plot 62 comprising wafers having circuit devices formed with a (two layer) Co/TiN cap (no nitrogen content) and a second plot 65 comprising wafers having circuit devices formed with a Co/W cap (no nitrogen content). Attempts to implement a W sputter deposited cap in the past have been plagued by voids in the silicide and bridging, leaving only a small temperature and thickness window in which it would work.

Despite the current state of the art, there is a continued need to develop new and improved silicide processes which do not have any of the problems mentioned with the prior art processes.

### SUMMARY OF THE INVENTION

One object of the present invention is to provide a semiconductor structure and method of fabricating a semiconductor structure having reduced gate and source/drain sheet resistances.

Another object of the present invention is to provide an improved self-aligned silicide process (salicide process) for a semiconductor transistor or memory device structure exhibiting reduced gate and source/drain sheet resistance.

An additional object of the present invention is to provide maximum utilization of the metal deposited in S/D regions between narrowly spaced gates where the amount of metal deposited from the sputter source may be reduced by shielding from the gate structures.

Alternatively another objective of deposition on a source drain/structure bounded by trench isolation is that excessive silicide growth out of the S/D region does not occur due to Si movement from out of the active area.

Yet another object of the present invention is to provide an improved self-aligned suicide process (salicide process) that includes depositing a composite cap layer that exhibits a lower stress build-up and lower nitrogen penetration than in the conventional TiN cap process used in forming a semiconductor transistor or memory device structure.

Thus, according to the invention, such a composite cap structure is employed in a salicide process that includes a top layer providing a penetration barrier against oxygen, i.e., Ti or Co, and an intermediate layer adjacent to the silicide forming metal such as W or Mo that prevents the oxygen barrier from reacting with the silicide forming materials. The composite silicide cap provides a barrier to oxygen penetration into the metal used to form the silicide, and additionally has mechanical properties that allow selective formation of silicide on active areas, but not over insulators with out excessive mechanical energy build up within the cap and metal layer that leads to voiding and bridging of the silicide. That is, the provision of a thin W layer of about 5 nm thickness in the composite cap structure reduces the stress effects and high Young's modulus of this material (over TiN) and, with an additional counter layer of Co or Ti on top, reduces oxygen penetration and provide a counter tensile stress layer to reduce the mechanical energy of the composite stack.

A further object of the present invention is to provide a method of fabricating a semiconductor structure having a silicide region formed atop the gate region and atop the source/drain regions and which employs processing steps which are compatible with existing MOSFET manufacturing processes.

These and other objects and advantages are obtained in the present invention by forming a silicide cap for a Si-containing semiconductor structure, the cap comprising:

a layer of metal formed atop an exposed surface of the Si -containing structure for forming a silicide region atop the exposed surface;

an intermediate metal barrier layer atop the silicide forming metal layer; and,

an oxygen barrier layer atop the intermediate metal barrier layer, wherein, as a result of an applied anneal to the structure, a silicide region is formed that exhibits improved sheet resistance.

It should be understood that, in an alternate processing environment where the oxygen levels are low enough (<1 ppm) that oxidation does not interfere with the silicidization process, the layer of metal formed atop an exposed surface of the Si -containing structure for forming a silicide region may be used alone without a capping layer.

In broad terms, the self-aligned silicide (salicide) process for forming a cap structure for a semiconductor device according to the present invention comprises the steps of:

providing a semiconductor substrate;

forming a MOSFET structure comprising a gate insulator on the substrate; and a transistor gate electrode on the gate insulator layer, wherein forming of the gate electrode comprises steps of:

forming a Si-containing layer;

forming a layer of metal formed atop the Si-containing layer used in forming a silicide region atop the transistor gate electrode;

forming an intermediate metal barrier layer atop the silicide forming metal layer; and,

forming an oxygen barrier layer atop the intermediate metal barrier layer; and,

annealing the MOSFET structure to form a resulting silicide region exhibiting a lower sheet resistance.

### BRIEF DESCRIPTION OF THE DRAWINGS

Further features, aspects and advantages of the apparatus and methods of the present invention will become better understood with regard to the following description, appended claims, and the accompanying drawings where:

FIGS 1A-1E are pictorial representations (through cross-sectional views) showing the basic processing steps of a prior art salicide process;

FIG. 2 depicts (through a cross-sectional view) potentially deleterious movement of materials during a silicide formation process according to the prior art;

FIG. 3 depicts the increased resistance exhibited by a silicide cap of a high N content TiN silicide layer formed in the prior art structure of FIG. 1C;

FIG. 4 depicts the reduced effects resistance exhibited by use of a Tungsten (W) cap in the formed prior art structure of FIG. 1;

FIG. 5 depicts the composite silicide cap structure according to the salicide processing according to the invention;

FIG. 6 depicts the resulting formed silicide regions formed out of the salicide processing employing the composite silicide cap structure according to the invention;

FIG. 7 depict examples of how a composite cap of W/Co can lower the sheet rho in the sheet rho data obtained from the inventive structure vs. a TiN/Co cap or conventional TiN cap; and,

FIG. 8 depicts (through a cross-sectional view) the improved mechanical properties from the materials implemented in the composite cap structure employed in a silicide formation process according to the invention.

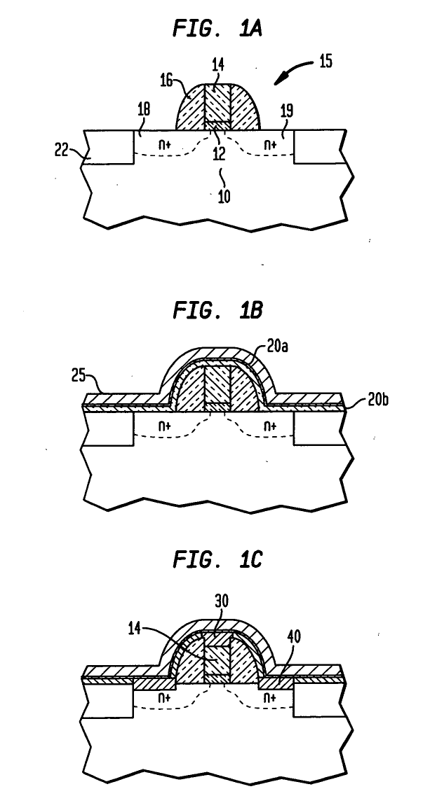

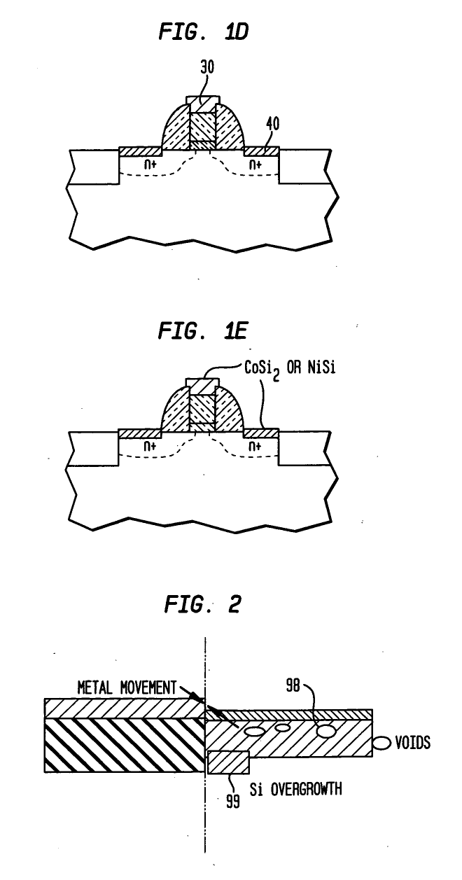

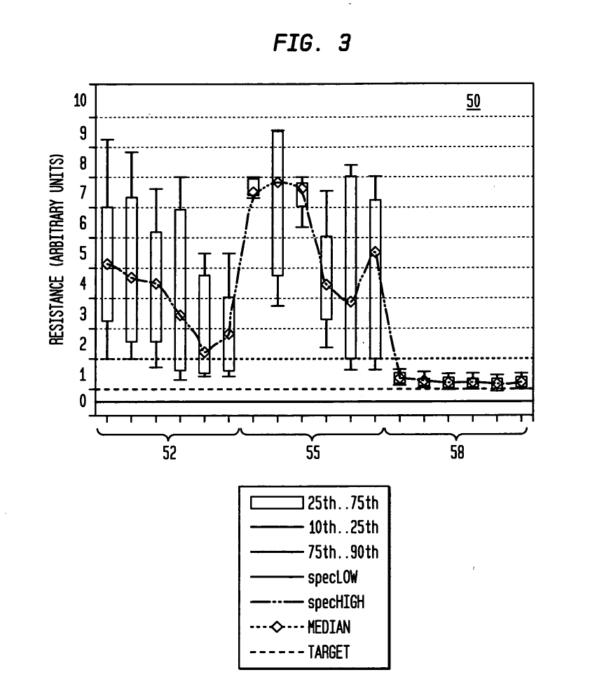

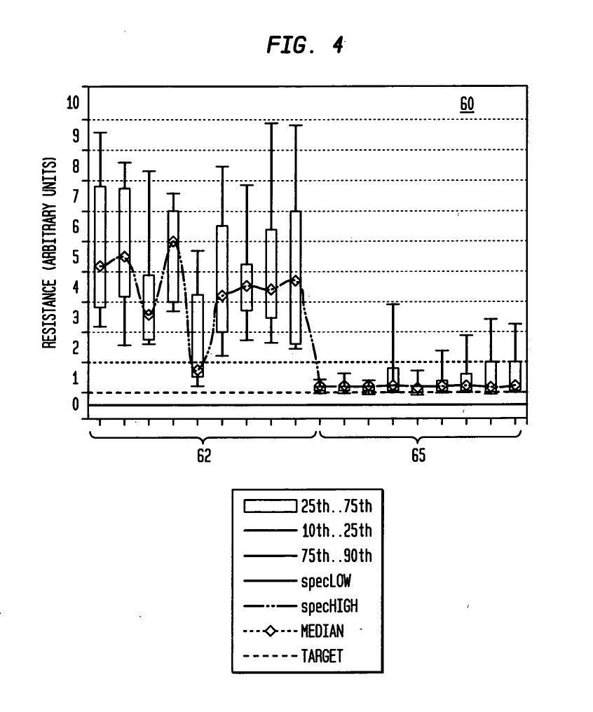

### DETAILED DESCRIPTION OF THE INVENTION

The present invention, which provides a method of fabricating a semiconductor transistor device structure having a silicide region formed atop the transistor source/drain regions and formed atop the transistor gate region, will now be described in greater detail.

According to the invention, a composite silicide cap structure resulting from a salicide process includes a top layer of material providing a penetration barrier against oxygen, e.g., Ti or Co, and an intermediate layer of material adjacent to the silicide forming metal such as W, or molybdenum (Mo) that prevents the oxygen barrier from reacting with the silicide forming materials. The silicide cap provides a barrier to oxygen penetration into the metal used to form the silicide, and additionally has mechanical properties that allow selective formation of silicide on active areas, but not over insulators with out excessive mechanical energy build up within the cap and metal layer that leads to voiding and bridging of the silicide.

This composite cap layer additionally does not raise the sheet resistance of the silicide formed underneath it by interdiffusing or adding extraneous materials such as nitrogen to the growing silicide film. The composite cap layer additionally has mechanical properties that allows it to flex over areas where silicide is formed and not move over areas where the metal below it covers insulators and does not react. Tungsten (W) layers, which are inert and provide the lowest sheet rho possible have a high Young's modulus which are used for this layer, must be thin enough so the total mechanical energy build up during silicide formation is minimized.

Both of these materials are etchable from the solidified formed below in a conventional silicide etch process. That is, W, Ti, and Co can easily be etched in peroxide sulfuric solutions, for example or fluorine based dry etching for W and Ti.

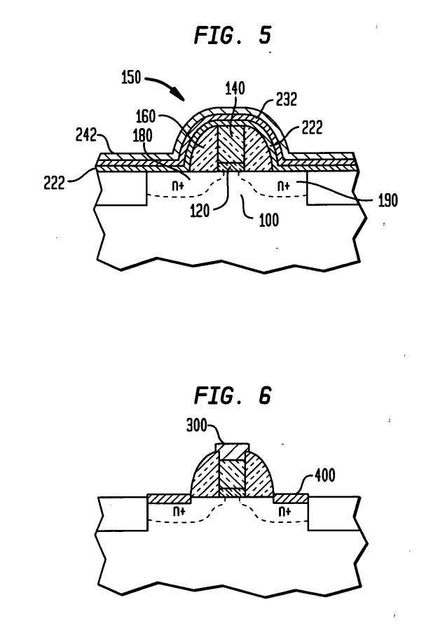

Embodiments of the present invention include forming a transistor device having a gate electrode on a silicon (Si)-containing semiconductor substrate in a conventional manner. FIG. 5 particularly depicts a formed transistor device, e.g., a MOSFET 150, having the composite silicide cap structure according to the invention. With view of FIG. 5, there is provided an initial transistor device 150 comprising a semiconductor substrate 100, gate dielectric material 120 formed on a surface of semiconductor substrate 100, and at least one patterned gate conductor 140 formed on a portion of gate dielectric material 120, e.g., polysilicon. It should be noted that although the drawings show the presence of only a single patterned gate conductor formed atop gate dielectric material 120, the present invention works equally well when a plurality of patterned gate conductors are employed.

The structure shown in FIG. 5 is comprised of conventional materials well known in the art and it is fabricated utilizing processing steps that are also well known in the art. For example, semiconductor substrate comprises any semi-conducting material including, but not limited to: Si, Ge, SiGe, GaAs, InAs, InP and all other III/V semiconductor compounds. A semiconductor substrate 100 may also include a layered substrate comprising the same or different semi-conducting material, e.g., Si/Si or Si/SiGe, as well as a silicon-on-insulator (SOI) substrate. The substrate may be of the n-or p-type depending on the desired device to be fabricated.

Additionally, it is understood that the semiconductor substrate may include active device regions, wiring regions, isolation regions, well regions or other like regions that are typically present in MOSFET-containing devices. For clarity, these regions are not shown in the drawings, but are nevertheless meant to be included. In one highly preferred embodiment of the present invention, semiconductor substrate 100 is comprised of Si or an SOI substrate.

The gate dielectric material may comprise an oxide, nitride, oxy-nitride or any combination and multilayer thereof, and may be formed on a surface of semiconductor substrate 100 utilizing a deposition process such as chemical vapor deposition (CVD), plasma-assisted CVD, evaporation, atomic layer deposition or chemical solution deposition (CSD). Alternatively, the gate dielectric material may be formed by a thermal growing process such as oxidation, nitridation or oxy-nitridation.

The thickness of the gate dielectric material formed is not critical to the present invention, but typically, gate dielectric material 120 has a thickness of from about 1 to about 20 nm after deposition. It is noted that the gate dielectric material employed in the present invention may be a conventional dielectric material such as SiO₂ or Si₃N₄, or alternatively, high-k dielectrics such as oxides of Ta, Zr, Hf, AI or combinations thereof may be employed. In other preferred embodiments of the present invention, gate dielectric material 120 is comprised of an oxide such as SiO₂, ZrO_{2,} HfO₂, Ta₂O₅ or AI₂O₃.

After forming gate dielectric material 120 on the surface of semiconductor substrate 100, at least one patterned gate conductor 140 is formed atop the layer of gate dielectric. The patterned gate conductor is formed utilizing a conventional process which includes the steps of: depositing at least a gate material on the gate dielectric material, and patterning the gate material via lithography and etching. The gate material may be deposited by CVD, plasma-assisted CVD, evaporation, plating or chemical solution deposition, while the lithography step includes applying a photo-resist to the gate material, exposing the photo-resist to a pattern of radiation and developing the pattern utilizing a conventional developer solution. Etching is performed utilizing a dry etching process such as reactive-ion etching, plasma etching, ion beam etching or laser ablation. Following the etching process, the photo-resist is removed from the structure utilizing a conventional stripping process well known in the art.

In one embodiment of the present invention (not shown in the drawings), the exposed portions of the gate dielectric (not containing the patterned resist or the patterned gate conductor) is etched at this point of the present invention. This provides an initial structure having exposed surfaces of semiconductor substrate 100 and patterned gate regions that include patterned gate conductors formed atop patterned gate dielectrics. Although the present invention contemplates removing the gate dielectric at this point of the inventive process, it is preferred to keep the gate dielectric material on the substrate during the subsequent diffusion implants. Following the various implant steps, in particularly, the ion implantation of the source/drain regions 180, 190, portions of the gate dielectric, which are not underneath either the sidewall spacers or the patterned gate conductor, are removed.

It is noted that each of patterned gate conductors 140 shown in FIG. 5 includes at least a gate material in which at least the top portion thereof is composed of a Si-containing material such as polysilicon or amorphous Si. The term “gate material” as used herein denotes a conductive material, a material that can be made conductive via a subsequent process such as ion implantation, or any combination thereof. Illustrative examples of suitable gate materials that can be employed in the present invention include, but are not limited to: polysilicon, amorphous silicon, SiGe, SiGeC, elemental metals such as W, Pt, Pd, Ru, Rh and Ir, alloys of said elemental metals, suicides or nitrides of these elemental metals, and combinations thereof, e.g., a gate stack including a layer of polysilicon and a layer of conductive metal. A highly preferred gate material employed in the present invention is a gate material that is comprised of polysilicon or amorphous silicon.

It is noted that in embodiments wherein a gate stack is employed, e.g., a stack of polysilicon and elemental metal, an optional diffusion barrier (not shown in the drawings) may be formed between each layer of the gate stack. The optional diffusion barrier, which is formed utilizing conventional deposition processes such as those mentioned hereinabove, is comprised of a material such as SiN, TaN, TaSiN, WN, TiN and other like materials which can prevent diffusion of a conductive material therethrough.

An optional anneal step may follow the implant steps. Although various annealing conditions may be employed in the present invention, it is preferred that annealing be conducted using a rapid thermal anneal (RTA) process which is carried out at a temperature of from about 900° to about 1150° C. for a time period of from a few milliseconds to about a minute or more.

Next, sidewall spacers 160 are formed atop the gate dielectric (or if the gate dielectric has already been removed, atop the substrate) so as to cover exposed vertical sidewalls of the patterned gate conductors by deposition and anisotropic etching. The sidewall spacers are composed of any insulator material including oxides, nitrides, oxy-nitrides or any combination thereof including multi-layers. A highly preferred insulator material for sidewall spacers 160 is a nitride such as SiN. The structure including the source/drain extension implants and sidewalls spacers is shown in FIG. 5.

Next, and as illustrated in FIG. 5, source/drain regions 180,190 are formed into substrate 100 by ion implantation and annealing. The ion implantation step, which includes the use of n-type dopant species as well as p-type dopant species, is carried out using implant conditions well known to those skilled in the art. The annealing step is performed using any anneal conditions that are capable of activating the source/drain regions. Preferably, this annealing step is performed using a RTA process that is carried out at a temperature of from about 900° to about 1150° C. for a time period of from a few milliseconds to about a minute or more.

At this point of the present invention, and if not previous done, gate dielectric material 120 that is not protected by either the sidewall spacers or the patterned gate conductor is removed utilizing a conventional etching process that is highly selective in removing the exposed gate dielectric from the structure. The resultant structure that is formed after this etching step is performed is shown in FIG. 5.

Next, as shown in FIG. 5, a first metal layer 222 is formed atop all exposed surfaces of the structure shown in FIG. 5 utilizing a conventional deposition process such as chemical vapor deposition, physical vapor deposition, metal organic chemical vapor deposition, evaporation or electroplating. The metal layer 222 is comprised of any metal which, when present atop a Si-containing surface, is capable of being converted into a silicide when subjected to annealing In the structure illustrated, silicide will be formed over source/drain regions 180,190 as well on the top surface of patterned gate region 140. During this film deposition process, the silicide metal layer comprises Co or Ni is deposited to a thickness required to give adequate sheet rho, however, other suitable metals for metal layer 222 include, but are not limited to: Pd, Pt, Ti, CoSi, NiPt, NiPtRe, NiTa, or W. A highly preferred metal for metal layer 222 is Co. The thickness of the metal layer formed at this point of the present invention may vary, typically however, metal layer 220 has a thickness, after deposition, of from about 50 to about 200 Å.

According to the invention, a thin intermediate capping layer 232, e.g., W, is then deposited to a thickness ranging anywhere between 1 nm-50 nm thick, and preferably, to approximately 5 nm thick, over the metal silicide forming layer 222. The intermediate metal cap layer 232 is deposited in a vacuum followed by a top metal capping layer 242, e.g., of Co, Ti, TiN and the like, to a thickness of approximately 20 nm or less. The film stack on a patterned semiconductor wafer is then annealed and etched according to a conventional salicide process. The resulting silicide layer exhibits a lower sheet rho due to lower stress build up and lower nitrogen penetration than a conventional TiN cap process.

Annealing is performed to form first silicide regions in areas of the structure that include a metal layer/Si-containing interface. Annealing is performed at this step of the present invention at a temperature of about 500° C. or higher for a time period of from about 1 second or greater. Preferably, and in embodiments when Co is employed as the metal layer, annealing is performed at a temperature of about 550° C. for about 90 seconds. Annealing is typically performed in an inert gas ambient such as He, Ar, N₂, Xe, or Kr. Mixtures of the aforementioned inert gases such as He-Ar or Ar-N₂ are also contemplated.

After the annealing is performed, the formed composite capping layer is removed from the structure using a chemical etchant that is highly selective in removing the capping layers. For example, when TiN is employed, the TiN layer is removed after annealing using a peroxide sulfuric solution. Any non-reacted metal, not converted into a suicide that may be present atop the capping layer is first removed using a chemical etchant that does not attack silicide. An exemplary selective wet etchant that can be employed in removing the non-reacted metal is a solution of nitric acid or peroxide sulfuric solutions to remove the unreacted metal.

It should be noted that in some embodiments of the present, a second annealing step may follow the initial silicide anneal. When a second annealing step is employed, the second annealing is carried out at a temperature of about 700° C. or greater for a time period of about 1 minute or less.

It is thus understood that, according to the invention, the top metal capping layer 242 such as Co, Ni, Ti, TiN, TiW, Cr and WN where the percent ratio of nitrogen to W ranges from 0.5-2.0, or like metal or metal compound of the composite silicide cap structure is provided to function as a penetration barrier against oxygen, e.g., during annealing; and, between the metal forming silicide layer 222 and the top metal capping layer 242, the formed intermediate cap layer 232 prevents the oxygen barrier from reacting with the silicide forming materials. Preferably, this intermediate layer 232 is formed of tungsten, W, or tantalum, Ta, atop the metal layer 222 to protect the metal layer from the penetration barrier layer. It is understood that presence of the thin intermediate layer 232 does not raise the sheet resistance of the silicide formed underneath it by inter-diffusing or adding extraneous materials such as nitrogen to the growing silicide film. This intermediate layer 232 additionally exhibits mechanical properties that allow it to flex over areas where silicide is formed and not move over areas where the metal below it covers insulators and does not react. Tungsten (W) layers, which do not involve nitrogen in the deposition process and provide the lowest sheet rho possible, but have a high Young's modulus which are used for this layer, must be thin enough so the total mechanical energy build up during silicide formation is minimized.

The resultant structure including silicide regions is shown in FIG. 6. First silicide regions 300, 400 are thin, self-aligned silicide regions whose thickness does not substantially penetrate through the source/drain regions. The term “thin” silicide is used herein to denote a silicide region having a thickness of from about 10 to about 50 nm, with a thickness of from about 20 to about 40 nm being more highly preferred.

Thus, in a preferred embodiment of the invention, the invention proposed is to use a thin W layer of approximately 5.0 nm to reduce the stress effects and high Young's modulus of this material over TiN but put a counter layer of Co on top to reduce oxygen penetration and provide a counter tensile stress layer to reduce the mechanical energy of the composite stack. That is, the combination of the composite stack capping W/Co is tensile metal on tensile metal.

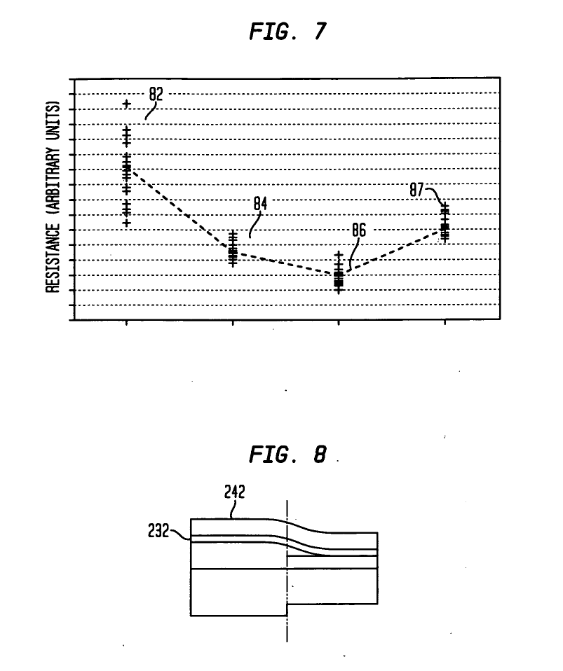

Examples of how a composite cap of W/Co can lower the sheet rho vs. a TiN/Co cap or conventional TiN cap are shown in the sheet rho data obtained from the inventive structure as now shown in FIG. 7. The poly sheet rho is always higher and has more fliers with a conventional cap (e.g., a Co/TiN cap of 70 nm/170 nm thick) as indicated at split 82, FIG. 7. As further shown, a Co/TiN/Co cap (i.e., of 70 nm/100 nm/100 nm thick) lowers the sheet rho and reduces the flier distribution as shown in split 84. Even further reductions in sheet rho are achieved with a Co/W/Co cap (i.e., of 70 nm/20 nm/50 nm thick) in split 85 according to the invention.

According to a second embodiment of the invention, the silicide cap with an oxygen barrier layer 242 and an intermediate metal barrier layer 232 (FIG. 5) are designed to minimize the total mechanical stress of the cap and underlying layer to reduce unwanted metal or silicon movement from reacting layers underneath. In this embodiment the top oxygen barrier 242 has an opposing stress to the intermediate metal barrier layer 232. For example, compressive TiN is used for the oxygen barrier 242 on top of a tensile W barrier layer 232. Referring back to FIG. 7, it is shown that adding a compressive layer, e.g., TiN, above the tensile W layer of the composite cap structure according to the second embodiment of the invention (i.e., a Co/W/TiN cap of 70 nm/25 nm/50 nm thick) raises the sheet rho, as shown in split 87, FIG. 7. This indicates that the nitrogen coming out of the TiN may be more influential on the sheet rho than the net stress of the film, which should be more balanced toward zero in split 87, FIG. 7. While the average sheet rho is higher for this structure, the sheet rho at narrow gate lengths is lower than the structure in the first embodiment due to the lower mechanical stress' built during silicide formation by this film. This type of cap structure should reduce unwanted voiding and bridging on the narrowest width gate structures and reduce unwanted sheet rho fliers.

Thus, as shown in FIG. 8, the added compressive oxygen barrier layer 242, e.g., TiN, above the tensile W layer 232 of the composite cap structure according to the second embodiment of the invention acts to reduce unwanted metal or silicon movement from reacting silicide forming layers underneath, thus improving resistive properties of the formed silicide.

In a third embodiment of this invention, in a processing environment where the oxygen levels are low (on the order of less than 1.0 parts per million), no cap layer is utilized. In this configuration, no materials from a cap are incorporated into the silicide which would potentially raise its resistivity, i.e., the need to form intermediate metal and top oxygen barrier layers according to the first and second embodiments is obviated. There is no stress build up at the junction of a silicide and metal over an insulator with subsequent unwanted material movement across the boundary between them leading to unwanted voiding and/or bridging.

While the present invention has been particularly shown and described with respect to preferred embodiments thereof, it will be understood by those skilled in the art that the foregoing and other changes in forms and details may be made without departing from the spirit and scope of the present invention. It is therefore intended that the present invention not be limited to the exact forms and details described and illustrated, but fall within the scope of the appended claims.

Having thus described our invention in detail, what we claim as new and desire to secure by the Letters Patent is:

What is claimed is:

1. A suicide cap for an Si-containing semiconductor structure comprising:
a layer of metal formed atop an exposed surface of said Si -containing structure for forming a suicide region atop the exposed surface;
an intermediate metal barrier layer atop said silicide forming metal layer; and,
an oxygen barrier layer atop said intermediate metal barrier layer, wherein, as a result of an applied anneal to said structure, a silicide region is formed that exhibits improved sheet resistance.

2. The silicide cap structure of claim 1, wherein said intermediate metal barrier layer exhibits tensile stress, said formed oxygen barrier layer comprising a compressive material for minimizing a total mechanical stress of the cap structure and underlying layers.

3. The silicide cap structure as claimed in claim 1, wherein said layer of metal formed atop an exposed surface of said Si-containing structure for forming a silicide region atop the exposed surface is formed in a processing environment having low oxygen levels, thereby obviating the need for said intermediate metal and oxygen barrier layers of said cap structure.

4. The silicide cap structure of claim 1, wherein said layer of metal formed atop said Si-containing structure for forming a silicide comprises Co, CoSi, Ni, Pd, Pt, Ti, NiPt, NiPtRe, NiTa, or W.

5. The silicide cap structure as claimed in claim 1, wherein said intermediate metal barrier layer is tungsten (W), tantalum (Ta), or molybdenum (Mo).

6. The silicide cap structure as claimed in claim 5, wherein said intermediate metal barrier layer ranges in thickness between 1 nm-50 nm.

7. The silicide cap structure as claimed in claim 5, wherein said oxygen barrier layer prevents oxygen from reacting with silicide forming materials.

8. The suicide cap structure as claimed in claim 7, wherein said oxygen barrier layer comprises Co.

9. The silicide cap structure as claimed in claim 7, wherein said oxygen barrier layer comprises Ti, TiN, WN, Cr, TiW.

10. The silicide cap structure as claimed in claim 2, wherein said formed intermediate metal barrier layer and oxygen barrier layers of said cap structure act to reduce unwanted metal or silicon movement from reacting silicide forming layers underneath.

11. The silicide cap structure as claimed in claim 2, wherein said Si-containing semiconductor structure comprises a MOSFET device comprising a gate insulator on the substrate; and a transistor gate electrode on the gate insulator layer, said cap structure utilized for forming a silicide region atop the transistor gate electrode.

12. The silicide cap structure as claimed in claim 11, wherein said MOSFET device further comprises:
sidewall spacers formed on opposing side surfaces of said gate electrode; and,
source/drain diffusion regions in the substrate adjacent the opposing side surfaces of the gate electrode, said cap structure utilized for forming silicide regions atop each said source/drain diffusion regions that exhibit improved sheet resistance.

13. The silicide cap structure as claimed in claim 1, wherein said Si-containing structure comprises polysilicon.

14. A self-aligned silicide (salicide) process for forming a cap structure for a semiconductor device comprising the steps of:
providing a semiconductor substrate;
forming an Si-containing structure at a surface or on top of said substrate;
forming a layer of metal layer atop an exposed surface of said Si -containing structure for forming a silicide region atop the exposed surface;
forming an intermediate metal barrier layer atop said silicide forming metal layer; and, forming an oxygen barrier layer atop said intermediate metal barrier layer; and, annealing said cap structure to form a resulting silicide region exhibiting a lower sheet resistance.

15. The salicide process of claim 14, wherein said intermediate metal barrier layer exhibits tensile stress, said formed oxygen barrier layer comprising a compressive material for minimizing a total mechanical stress of the cap structure and underlying layers.

16. The salicide process as claimed in claim 14, wherein said step of forming a layer of metal atop an exposed surface of said Si-containing structure for forming a silicide region atop the exposed surface comprises: providing a processing environment having low oxygen levels to thereby obviate the need for subsequent steps of forming said intermediate metal barrier and oxygen barrier layers of said cap structure.

17. The salicide process of claim 15, wherein said layer of metal formed atop said Si-containing layer for forming a silicide comprises Co, CoSi, Ni, Pd, Pt, Ti, NiPt, NiPtRe, NiTa, or W.

18. The salicide process of claim 14, wherein said intermediate metal barrier layer is tungsten (W), tantalum (Ta), or molybdenum (Mo).

19. The salicide process of claim 14, wherein said oxygen barrier layer prevents oxygen from reacting with the silicide forming materials during said annealing step.

20. The salicide process of claim 19, wherein said oxygen barrier layer comprises Co.

21. The salicide process of claim 19, wherein said oxygen barrier layer comprises Ni, Ti, TiN, TiW, Cr or WN.

22. The salicide process of claim 15, wherein during said annealing step, the step of reducing unwanted metal or silicon movement from reacting silicide forming layers underneath.

23. The salicide process of claim 15, wherein said step of forming an Si-containing structure at a surface or on top of said substrate comprises steps of: forming a MOSFET structure comprising a gate insulator on the substrate, and a transistor gate electrode on the gate insulator layer;
forming sidewall spacers formed on opposing side surfaces of said gate electrode; and,
forming source/drain diffusion regions in the substrate adjacent the opposing side surfaces of the gate electrode, wherein silicide regions are formed atop each said gate electrode and source/drain diffusion regions that exhibit improved sheet resistance.

24. The salicide process of claim 23, wherein said silicide regions are formed atop each said source/drain diffusion region by annealing.

25. A self-aligned silicide (salicide) process for forming a semiconductor device comprising the steps of:
a) providing a semiconductor substrate;
b) forming a MOSFET structure comprising a gate insulator on the substrate; and a transistor gate electrode on the gate insulator layer, wherein forming of the gate electrode comprises steps of:
forming a Si-containing layer;
forming a layer of metal in a low oxygen environment atop said Si-containing layer used in forming a silicide region atop the transistor gate electrode;
c) annealing said MOSFET structure to form a resulting silicide region exhibiting a lower sheet resistance.

26. A silicide structure for a Si containing semiconductor structure comprising a layer of metal formed atop an exposed surface of an Si-containing structure for forming a silicide region atop the exposed surface in a processing environment having oxygen levels obviating need for a capping layer.
